(19) United States
(12) Patent Application Publication
(10) Pub. No.: US 2008/0160215 A1
(43) Pub. Date: Jul. 3, 2008

(54) Contamination Resistant Surfaces

(75) Inventors: Mark Crowder, Westminster, CO (US); Christina Haley, Longmont, CO (US)

Correspondence Address: SHERIDAN ROSS PC, 1560 BROADWAY, SUITE 1200, DENVER, CO, 80202, US

(73) Assignee: Ball Aerospace & Technologies Corp., Boulder, CO (US)

(21) Appl. No.: 11/617,662

(22) Filed: Dec. 28, 2006

(51) Int. Cl. C23C 16/50; B05D 5/06

(52) U.S. Cl. 427/580; 427/255.6; 427/595; 427/162

(57) ABSTRACT

The invention provides a fluorocarbon coating having a reduced surface energy that has low susceptibility to molecular and particulate contamination. The fluorocarbon coating is stable and functional in vacuum. The fluorocarbon coating is stable to chemical solvents, cryogenic temperatures, and temperatures as high as 400° C. The fluorocarbon coating may be deposited as a thin film or produced as a modification to a surface of optical instruments without significant alteration of the optical characteristics. The fluorocarbon coating may reside on a textured substrate or include texturing within the process to further enhance the contamination resistant qualities of the treated surface. The fluorocarbon coating may be graded in composition throughout the coating layer. The invention can be used on surfaces that operate in aerospace environments and in dusty environments where contamination is an important consideration.

### FIELD

The present invention relates to contamination resistant coatings on surfaces or the modification of surfaces to achieve contamination resistance.

### BACKGROUND

Providing surfaces that are easily cleaned or that have self-cleaning properties is desirable in connection with a wide range of applications. For example, self-cleaning exterior panels on vehicles could reduce or eliminate the need for owners to expend time and resources washing such vehicles. Similarly, in architectural applications, self-cleaning surfaces could reduce or eliminate the need to have window washers perform the potentially dangerous task of washing windows and other exterior building surfaces.

In order to achieve a self-cleaning or contamination resistant surface, one approach is to provide a surface having a low surface energy. Typically, this can be achieved by applying a fluorochemical polymer film. An example of such polymers is the Scotchgard™ line of products available from 3M Corporation. Another approach to reducing the effective surface energy of a surface is to introduce surface roughness. In particular, by providing a surface having a roughness with peaks separated by valleys, the contact area between the surface and contaminants is minimized.

Many industries and research endeavors depend on maintaining environments for the construction and operation of devices that are free from environmental contaminants. One example is found in the construction of satellites and spacecraft. For instance, during the construction of a typical satellite, components and assemblies are subjected to a vacuum baking process to remove impurities before final assembly and launch. The vacuum baking process can take weeks. Therefore, maintaining contaminant-free components represents a major consumption of time and money. Accordingly, it would be desirable to provide components with surfaces that accumulate contamination more slowly, and/or were easier to clean, in order to reduce vacuum baking times. Moreover, surfaces with such characteristics would remain cleaner while in operation, potentially extending the service life of the devices, particularly when they are essentially inaccessible. However, the polymer films typically used to provide low surface energy surfaces tend to volatize, evaporate and/or sublimate under the conditions introduced by vacuum baking, or even when operationally deployed, for example on an orbiting satellite or on a spacecraft. Moreover, the performance of such films also degrades as a result of exposure to high temperatures (e.g., greater than about 60° C.).

The requirements for contamination-free assembly and contamination resistance during operation are even more stringent in connection with optical elements deployed on or as part of a satellite or spacecraft. In addition, because such elements are carefully designed to transmit light efficiently and in a controlled manner, any films or surface treatment applied to the surface must not have an adverse effect on the optical performance of the optical element. Likewise, texturing of the surface of the optical element must avoid unduly degrading the performance of the element.

### SUMMARY

The present invention is directed to solving these and other problems and disadvantages of the prior art. In accordance with embodiments of the present invention, fluorocarbon precursor gases are used to create a modified surface and/or a film on a surface. In particular, the modified surface or the film comprises a fluorinated carbon film exhibiting low surface energy and a high resistance to deterioration in the presence of temperature and/or pressure extremes.

In accordance with embodiments of the present invention, a modified surface is created featuring a network of Carbon atoms and at least some Fluorine atoms. In preferred embodiments of the invention, the network of Carbon atoms is a carbon lattice. In further embodiments, the network of Carbon atoms is a diamond-like carbon coating.

The modified surface may represent a surface that has been reduced in thickness as a result of the surface modification treatment or an initial etching treatment to the surface prior to deposition of the carbon and fluorine network. In accordance with still other embodiments of the present invention, the surface modifications can include texturing of the deposited surface coating.

In accordance with other embodiments of the present invention, a thin film comprising a network of Carbon atoms with at least some Fluorine atoms is deposited on a surface. The thickness of the film is generally less than 100 Å, and preferably less than about 50 Å for optical applications. In preferred embodiments, the thickness of the film is between about 10 Å and about 90 Å. In other embodiments, the thickness of the film is between about 20 Å and about 50 Å. In other embodiments, the thickness of the film will exceed 100 Å. In accordance with further embodiments of the present invention, the deposition of a thin film can be achieved while simultaneously creating a surface roughness within the deposited film or can be deposited on a surface that has already been textured. In accordance with further embodiments of the present invention, a thin film can be deposited on a surface that is optimized for complimentary applications. For example, a low surface energy film can be deposited on an active or passive electrically or magnetically functioning surface.

In accordance with embodiments of the present invention, a method for creating a contamination-resistant surface through surface modification and/or film deposition is provided. The method includes introducing a precursor gas into a vacuum chamber containing a surface or substrate to be treated. The substrate may be electrically grounded, or connected to a current source. In addition, the substrate may be brought to an elevated temperature. As the precursor gas is admitted into the chamber, radio frequency energy is introduced to ignite a plasma. This may continue until the desired thickness of deposited film or depth of surface modifications has been reached. In accordance with still other embodiments of the present invention, an inert gas may be added to the chamber with the precursor gas. Embodiments of the method allow for deposition or surface treatment using ion beam direct or assisted processes, cathodic arc processes, or sputter deposition processes. Embodiments of the method allow for surface modification of a substrate, to create a fluorocarbon material at the surface and a surface having low surface energy. Embodiments of the present invention may also be used to deposit a diamond-like carbon film having low surface energy.

In accordance with a related embodiment of the present invention, a solid source may be sputtered or evaporated in the vacuum chamber in the presence of a reactant gas such as fluorine, a fluorocarbon, or a hydrofluorocarbon to produce the desired fluorocarbon material at the surface. This method includes introducing a precursor gas into a vacuum chamber containing a surface or substrate to be treated and a solid precursor target. The solid precursor may be a solid carbon or fluorocarbon or hydrofluorocarbon precursor. The substrate may be electrically grounded, or connected to a current source. In addition, the substrate may be brought to an elevated temperature. A reactant gas is admitted into the chamber. The reactant gas may be a fluorine or fluorocarbon or hydrofluorocarbon precursor gas that will react with components of the solid support to form the fluorocarbon material at the surface of the substrate. Radio frequency energy is introduced to ignite a plasma and energy is provided to the solid precursor to sputter or evaporate the solid precursor target in the presence of the reactant gas. This may continue until the desired thickness of deposited film or depth of surface modifications has been reached. An inert gas may be added to the chamber with the reactant gas. Embodiments of the method allow for deposition or surface treatment using ion beam direct or assisted processes, cathodic arc processes, or sputter deposition processes.

In accordance with still other embodiments of the present invention, the surface modification or deposition of a film may be accompanied by texturing of the surface resulting in decreased contact area between the surface and contaminants. The texturing may comprise nano-texturing, and may be sized so as to reduce the contact area between the surface and contaminant particles. In accordance with certain embodiments of the invention, the root mean square surface roughness may be as low as 2 Å to about 10 Å. This low root mean square surface roughness may be particularly useful for optical applications.

Additional features and advantages of embodiments of the present invention will become apparent from the following discussion, particularly when taken together with the accompanying drawings.

### BRIEF DESCRIPTION OF THE DRAWINGS

FIG. 1 is a schematic diagram of components of a system for treating a surface and/or depositing a contamination resistant coating in accordance with embodiments of the present invention.

FIG. 2 depicts a substrate with a contamination resistant coating in accordance with embodiments of the present invention formed thereon;

FIG. 3 depicts a substrate with a surface that has been modified for contamination resistance in accordance with embodiments of the present invention;

FIG. 4 is a flowchart depicting aspects of a method for depositing a contamination resistant coating and/or modifying a surface to provide contamination resistance in accordance with embodiments of the present invention.

### DETAILED DESCRIPTION

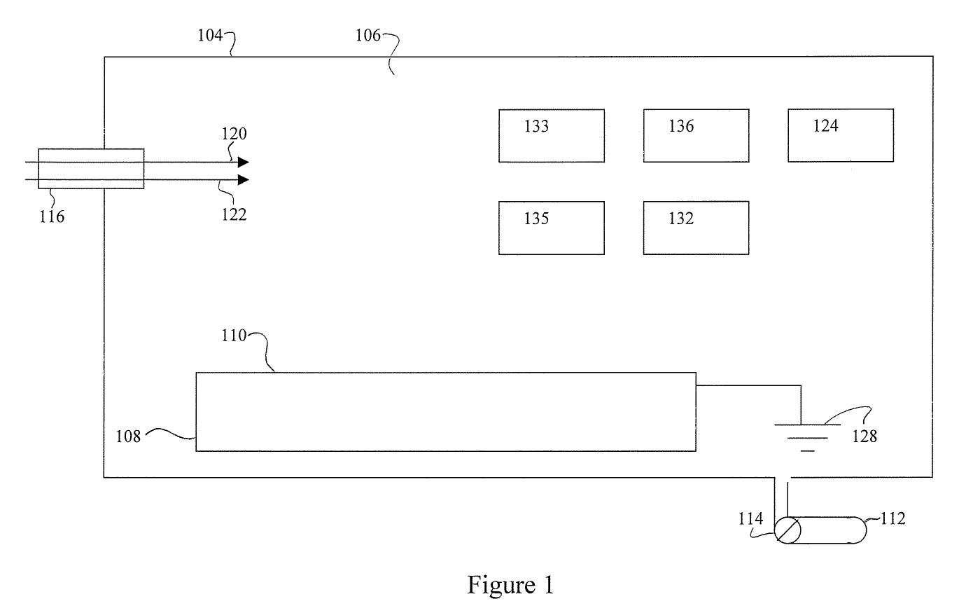

FIG. 1 depicts components of a system for depositing a contamination resistant coating or modifying the surface of a substrate to produce a contamination-resistant surface in accordance with embodiments of the present invention. In general, the arrangement includes a vacuum chamber 104 with an interior volume 106 sized to receive all or a portion of a substrate 108 having a surface 110 to be treated. In general, the vacuum chamber 104 is associated with a vacuum pump 112 and a throttle valve 114 for creating a vacuum within the interior 106 of the vacuum chamber 104, and a mass flow controller 116 for admitting a precursor gas 120 to the interior 106 of the vacuum chamber 104. The vacuum chamber 104 may additionally include or be associated with a radio frequency generator 124, an electrical ground or current source 128, a thermal energy source 132, a UV radiation source 133, a microwave radiation source 135 and/or an active cooling device 136.

In accordance with embodiments of the present invention, the precursor gas 120 comprises a fluorocarbon precursor gas, including hydrofluorocarbon gases. An example precursor gas is C₃F₆. In accordance with embodiments of the present invention, an inert gas 122 may be admitted into the interior 106 of the vacuum chamber 104 with the precursor gas 120. An example inert gas for use in connection with embodiments of the present invention is Argon. In general, the mass flow controller 116 and the throttle valve is controlled such that a flow of precursor gas 120 (and inert gas 122, if provided) is maintained generally across or around the surface 110 to be treated of the substrate 108, and such that a desired system pressure is maintained within the interior 106 of the vacuum chamber 104.

The radio frequency generator 124 generally operates to ignite a plasma. In accordance with embodiments of the present invention, the radio frequency generator 124 introduces energy having a frequency of 13.56 MHz. As an example, the radio frequency generator 124 may operate at a power of from about 1 watt to about 40 watts.

An electrical ground or an electrical current generator 128 may be connected to the substrate 108 including the surface 110 to be treated. Accordingly, the substrate 108 may be either electrically grounded or biased. For example, embodiments that provide a direct current bias may bias the substrate 108 at about −100 volts. In accordance with still other embodiments of the present invention, a pulsed direct current bias may be introduced at a voltage of about 100 Volts and a frequency of about 100 kHz.

A thermal energy source 132 may be included to elevate the temperature of the substrate 108. For example, a thermal energy source 132 comprising an electrical resistance heater can be included in the vacuum chamber 104. In accordance with embodiments of the present invention, a thermal energy source 132 may be used to increase the temperature of the substrate 108, to enhance the temperature resistance or assist in the control of surface modification and/or coating deposition then being performed on the substrate 108. An active cooling device 136 may be provided to cool the substrate 108.

An electromagnetic radiation energy source (such as a radio frequency energy source, a UV radiation source and/or a microwave energy source) may be included to add additional energy to the substrate 108. In accordance with embodiments of the present invention, a UV energy source 133 may be used to enhance the UV resistance or to assist in the control of surface modification and/or coating deposition being performed on the substrate 108.

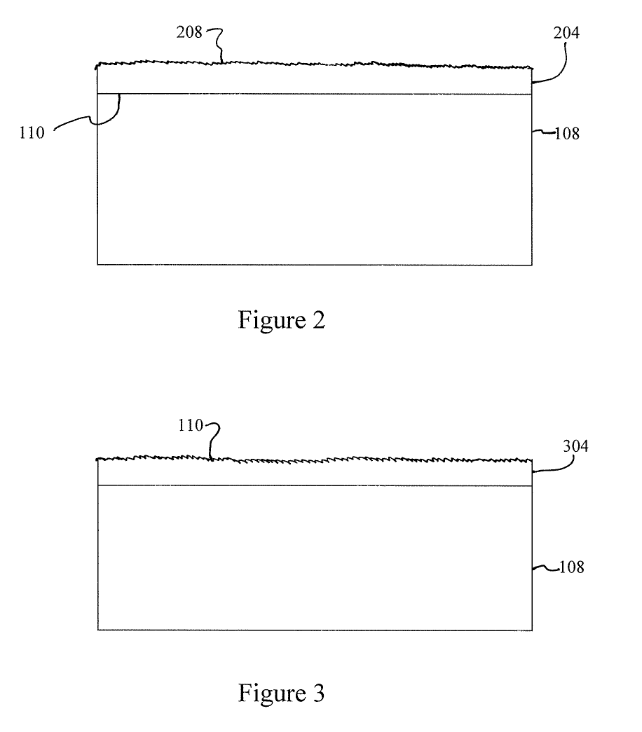

With reference now to FIG. 2, a substrate 108 on which a contamination resistant coating 204 in accordance with embodiments of the present invention has been deposited is depicted in cross-section. In general, the contamination resistant coating 204 comprises a fluorocarbon film. More particularly, the contamination resistant coating 204 comprises a lattice or network of carbon atoms with interspersed fluorine atoms. The carbon matrix may be diamond-like. The fluorine atoms may appear in greater abundance at the external surface of the carbon matrix. In accordance with embodiments of the present invention, the contamination resistant coating 204 is deposited on an optical surface. The contamination resistant coating 204 may comprise a monolayer or multilayer of approximately 7-25 Å. The thickness of the coating on optical elements is tailored to the wavelength operating range of the optical system. For example, ultraviolet applications preferably comprise a minimal or near minimal effective thickness. Visible wavelength operating systems may allow thicker depositions of 100 Å or greater. The ultimate film thickness is selected to optimize the optical system performance.

In FIG. 3, a substrate 108 with a surface 110 that has been modified to form a contamination resistant surface 304 is depicted in cross-section. According to such embodiments, the thickness of the substrate 108 may be about the same as the thickness of the substrate 108 prior to treatment. In accordance with still other embodiments of the present invention, the thickness of the substrate 108 may be reduced by the treatment. The surface modification 304 comprises the formation of a fluorocarbon material, having a matrix of carbon atoms in which fluorine atoms are interspersed. The depth of the surface modification 304 may be a monolayer of about 7 Å or greater.

As depicted in FIGS. 2 and 3, the surface 208 of the contamination resistant coating 204 (FIG. 2) or the surface 110 of a substrate 108 featuring surface modification 304 (FIG. 3) may be textured or nanotextured. This texturing may be dimensioned on the order of the interaction dimensions to further improve contamination resistance. More particularly, the distance between peaks in the carbon surface coating may be selected so as to minimize the contact area between the surface 110 or 208 and contaminants that come into contact with the surface, thereby decreasing the adsorbent-surface interaction. Texturing of the surface 110, 208 at angstrom levels as provided in accordance with embodiments of the present invention provides reduced contact areas with respect to particles that are about 1 micron to about 100 microns, such as may be encountered during the manufacture and operation of satellites and spacecraft. In addition, texturing the surface 110, 208 at such angstrom levels has no significant effect on the performance of optical elements so treated.

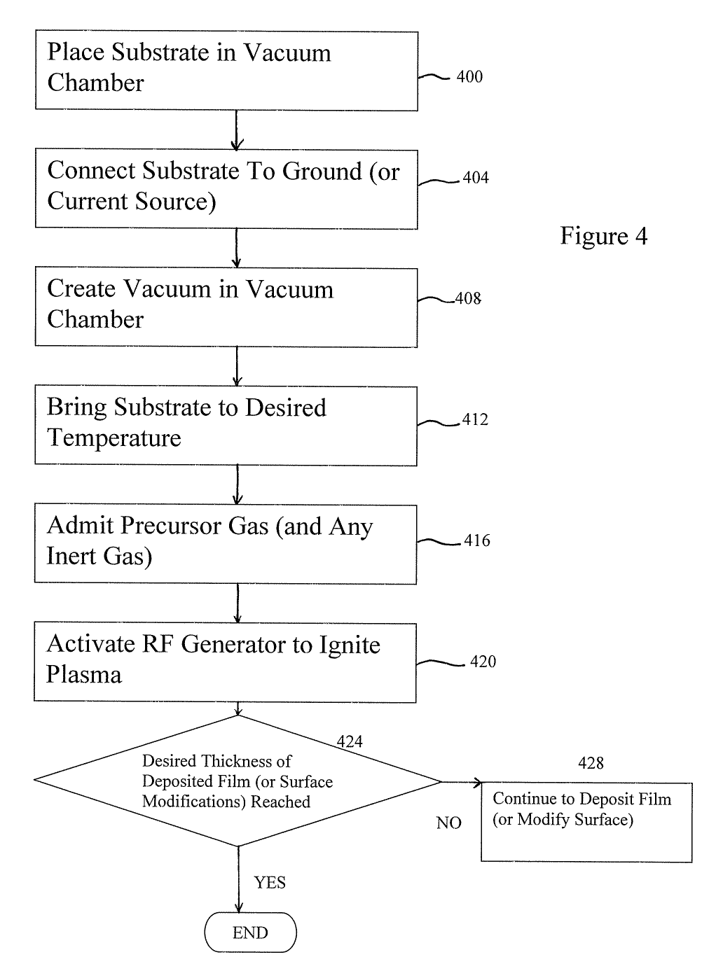

FIG. 4 is a flowchart illustrating aspects of a method for producing a contamination resistant coating 204 or surface modification 304 in accordance with embodiments of the present invention. Initially, at step 400, a substrate 108 to be treated is placed within the interior 106 of a vacuum chamber 104. The substrate 110 may be connected to ground or to a current source 128 (step 404). In general, connecting the substrate 108 to a current source 128 to introduce direct current or a pulsed direct current bias, and/or increasing the substrate temperature 108 using a thermal energy source 132 can be used to reduce the fluorine content in the contamination resistant coating 204 or region of surface modification 304, without degrading the net surface energy. The addition of a direct current substrate bias can be used to increase the growth rate of the contamination resistant film or coating 204 and/or improve adhesion to the substrate 108. At step 408, a vacuum is created within the interior 106 of the vacuum chamber 104. In accordance with embodiments of the present invention, the vacuum chamber 104 is pumped to a base pressure of near 1×10⁻⁶ Torr.

At step 412, the substrate 108 may be brought to a desired temperature, for example through operation of a thermal energy source 132 or an active cooling device 136. Typically, heating using a thermal energy source 132 and/or cooling using an active cooling device 136 may be performed throughout the deposition or surface modification process to maintain the substrate 108 at a desired temperature.

A precursor gas comprising a fluorocarbon is then admitted to the interior of the vacuum chamber 104 through the mass flow controller 116 (step 416). The throttle valve 114 is used to limit the pumping conductance to attain a system pressure of about 0.1 Torr. The precursor gas 120 may comprise, for example, perfluoropropene (C₃F₆). In accordance with still other embodiments of the present invention, a mixture of C₃F₆ and alternative precursors, such as C₃F₈ can be used. For instance, the addition of C₃F₈ to a precursor feed comprising C₃F₆ will decrease the deposition rate and add CF₃ functional groups to the upper surface of the contamination resistant coating 204 or area of surface modification 304, reducing the net surface energy of the film. In addition, an inert gas 122 may be admitted together with the precursor gas 120. For example, the range of operating pressures over which a stable plasma can be established may be extended by adding an inert gas, such as Argon. Moreover, the addition of Argon may allow a stable plasma to be created at low radio frequency powers, allowing finer control of deposition rates. Lower power operation also allows for a lower deposition temperature without requiring active cooling to maintain acceptable substrate temperatures.

The radio frequency generator 124 is activated to ignite a plasma in the precursor gas 120 (step 420). In accordance with embodiments of the present invention, the radio frequency generator 124 provides radio frequency energy at a frequency of 13.56 MHz. The radio frequency generator 124 may be operated to provide the radio frequency energy at powers of from about 1 Watt to more than 40 Watts.

At step 424, a determination is made as to whether the desired thickness of deposited contamination resistant film or coating 204 (or depth of surface modifications 304) has been reached. If the desired thickness or depth has not been reached, the process of depositing the coating or film 204 (creating a modified surface 304) is continued (step 428). Once the desired thickness of contamination resistant coating or depth of surface modifications has been reached, the process may end.

In general, by adding energy to the process, the roughness of the surface can be increased. That is, texturing can be introduced. Accordingly, increasing the power of radio frequency energy, the direct current bias on the substrate 108, or adding thermal energy may also increase the roughness of the surface and/or texture the surface. In accordance with further embodiments of the present invention, the surface can be textured by etching in a step performed separately from those steps used to produce a fluorocarbon film, for example using an ion beam assisted process. In accordance with yet further embodiments of the invention, the energy inputs, such as thermal energy and/or electromagnetic radiation (including, for example, microwave energy, UV radiation, and/or radio frequency energy), can be varied during deposition of the fluorocarbon film coating to form a graded coating that varies in composition throughout the thickness of the film. In some embodiments, the films may be graded in terms of density, hardness, and fluorine content. For example, in one preferred embodiment, the fluorine content of the film is greatest at the external surface of the film to minimize surface energy. The fluorine content of the film of this embodiment decreases throughout the body of the film approaching the substrate surface to increase film hardness and density. This graded film is formed by varying the energy input during the deposition from high energy at the start of the deposition to a lower energy as the deposition proceeds.

Specific processing conditions such as pressure, power, and bias detailed in the previous description are variables, which are dependent upon specific deposition systems. These conditions may vary with deposition system geometry and configuration.

Embodiments of the present invention provide a contamination resistant coating or a surface that has been modified to provide contamination resistance. The contamination resistant surfaces thus obtained are chemically resistant. As a result, they can be cleaned with commonly available chemicals, such as isopropyl alcohol. In addition, they are resistant to temperature extremes, including temperatures in excess of 300° C. The surface features low surface energy. For example, surfaces treated by depositing a coating or through surface modification as described herein have a surface energy of less than 25 dyne/cm and typically less than 20 dyne/cm and preferably about 18 dyne/cm. Moreover, the majority of this surface energy is dispersive. For example, the polar component of the surface energy is less than 15% of the surface energy and preferably less than about 5% of the surface energy or between about 0.5 dyne/cm to about 1.5 dyne/cm. The low surface energy achieved by embodiments of the present invention is evidenced by the high contact angles that can be achieved. For example, a contact angle of about 110° can be achieved by treating a surface as described in Example 1 below.

The following examples are provided for purposes of illustration only and are not intended to limit the scope of the invention.

### EXAMPLE 1

This example describes the deposition of a contamination-resistant coating on a component to create a surface having a low surface energy and contamination resistance.

Initially, an optical element, such as a lens, or other component having surfaces that are to be coated with a contamination resistant coating is placed in the vacuum chamber. After placing the component to be treated in the vacuum chamber, it is not electrically grounded. The pump of the vacuum chamber is operated to produce a pressure of about 1×10⁻⁶ Torr. The mass flow controller is then opened to admit a precursor gas comprising C₃F₆ into the chamber at a rate of 5 sccm, and the opening of the throttle valve is controlled to maintain a pressure of 0.2 Torr within the vacuum chamber. After admitting the precursor gas, a plasma is ignited by turning on the radio frequency generator to produce a 3 watt, 13.56 MHz signal. During the deposition process, the substrate sustains a self-bias, the magnitude of which depends on the substrate's electrical properties. This procedure is generally effective to deposit a film on the component being treated at a rate of approximately 30 Å every minute. The process described in connection with this example is performed at ambient temperature (e.g., about 23° C.). The water contact angle for this film is 109 degrees. The film, when exposed to temperatures up to 350° C., retains a low surface energy.

### EXAMPLE 2

This example relates to high temperature deposition to achieve contamination resistance. According to this example, a component to be treated is placed in the vacuum chamber. The vacuum chamber is then brought to a pressure of about 1×10⁻⁶ Torr. According to this example, the inlet valve is opened to admit a precursor gas comprising C₃F₆ at a rate of 5 sccm. The throttle valve is controlled such that the pressure within the vacuum chamber is maintained at about 0.2 Torr. The temperature of the substrate is brought to 100° C. using a radiative thermal energy source. After admitting the precursor gas, a radio frequency generator is operated to produce a 2 watt, 13.56 MHz signal. According to this example, a contamination resistant coating is deposited at a rate of about 10 Å per minute. The water contact angle for this film is 111 degrees.

### EXAMPLE 3

This example relates to modifying the surface of a component to be treated by exposing the surface to a plasma such that etching of the surface and deposition are essentially balanced, and there is no net deposition of a contamination resistant coating.

According to this example, a component to be treated for contamination resistance is placed in a vacuum chamber and is electrically grounded. The vacuum chamber is brought to a pressure of about 1×10⁻⁶ Torr. A precursor gas comprising C₃F₈s admitted into the chamber. The rate which the precursor gas is admitted is controlled to maintain a pressure of about 0.1 Torr within the chamber. After admitting the precursor gas, a plasma is ignited using a 5 watt, 13.56 MHz signal. According to this example, the component being treated is exposed to the plasma for about 10 minutes. This example is similar to Example 1; except, the precursor gas is a saturated fluorocarbon. As a result, the surface of the component being treated is modified with a low surface energy, without any net deposition of material or increase in the thickness of the treated component.

### EXAMPLE 4

This example relates to a higher energy deposition of a layer on a surface to achieve surface texturing. According to this example, a component to be treated is placed in the vacuum chamber and is connected to a DC current source. The vacuum chamber is then brought to a pressure of about 1×10⁻⁶ Torr. According to this example, the inlet valve is opened to admit a precursor gas comprising C₃F₆. The throttle valve is controlled such that the pressure within the vacuum chamber is maintained at about 0.6 Torr. After admitting the precursor gas, a radio frequency generator is operated to produce a 10 watt, 13.56 MHz signal. The deposited layer has a texture with a root-mean-square roughness of about 75 Å. The water contact angle of this film is 111 degrees.

### EXAMPLE 5

This example relates to deposition of a low surface energy film on a textured surface. According to this example, a component to be treated is prepared by adding nanoclusters onto a surface with a texture defined by a RMS roughness of less than about 10 Å. Alternatively, the nanoclusters of materials can be formed by self-assembled monolayers or self-organized nanotemplates. In this example, the treated surface has a texture resembling a dimpled surface with each nanocluster having a height of about 40 Å and a varied spacing of 50 to 400 Å between each nanocluster, producing a density of approximately 10¹¹ clusters/cm².

The textured component is then placed in the vacuum chamber and is electrically grounded. The vacuum chamber is brought to a pressure of about 1×10⁻⁶ Torr. According to this example, the inlet valve is opened to admit a precursor gas comprising C₃F₆. The valve is controlled such that the pressure within the vacuum chamber is maintained at about 0.1 Torr. The temperature of the substrate is brought to 50° C. using a thermal energy source. After admitting the precursor gas, a radio frequency generator is operated to produce a 2 watt, 13.56 MHz signal. According to this example, a contamination resistant coating is deposited at a rate of about 12 Å per minute.

### EXAMPLE 6

This example describes the deposition of a contamination-resistant coating on a component to create a surface having a low surface energy and describes the contamination resistance of the deposited coating.

A gold plated quartz crystal (for a quartz crystal microbalance, QCM) is placed in the vacuum chamber. The pump of the vacuum chamber is operated to produce a pressure of about 1×10⁻⁶ Torr. The mass flow controller is then opened to admit a precursor gas comprising C₃F₆ into the chamber at a rate of 5 sccm, and the opening of the throttle valve is controlled to maintain a pressure of 0.2 Torr within the vacuum chamber. After admitting the precursor gas, a plasma is ignited by turning on the radio frequency generator to produce a 2 watt, 13.56 MHz signal. The process described in connection with this example is performed at ambient temperature (e.g., about 23° C.). The quartz crystal is removed from the deposition chamber.

The coated quartz crystal is installed in a QCM, and an uncoated gold plated quartz crystal is installed in a second QCM. Both QCM's are installed into a vacuum chamber and held at ambient temperature (e.g., about 23° C.). The chamber is operated to produce a pressure of about 1×10⁻⁶ Torr, and the two adjacent QCMs are exposed to a flux of molecular contamination. The uncoated quartz crystal accumulated contamination at approximately two times the rate of contamination accumulated on the low surface energy coated quartz crystal. Thus, the low surface energy coating provided protection to molecular contamination.

### EXAMPLE 7

This example describes the deposition of a contamination-resistant coating on a component to create a surface having a low surface energy and describes the contamination resistance of said coating.

A silicon wafer is placed in the vacuum chamber. The pump of the vacuum chamber is operated to produce a pressure of about 1×10⁻⁶ Torr. The mass flow controller is then opened to admit a precursor gas comprising C₃F₆ into the chamber at a rate of 5 sccm, and the opening of the throttle valve is controlled to maintain a pressure of 0.2 Torr within the vacuum chamber. After admitting the precursor gas, a plasma is ignited by turning on the radio frequency generator to produce a 2 watt, 13.56 MHz signal. The process described in connection with this example is performed at ambient temperature (e.g., about 23° C.). The wafer is removed from the deposition chamber.

After coating deposition, the number and size of the particles on the coated wafer and the number and size of particles on a bare, uncoated silicon wafer were characterized. Both wafers were installed into a particle injection chamber in a vertical orientation. Arizona road dust was injected into the chamber. The number and size of particles on each wafer was characterized after removal from the particle injection chamber. The total number of particles that accumulated on the bare, uncoated silicon wafer exceeded the total number of particles that accumulated on the low surface energy coated wafer.

The foregoing discussion of the invention has been presented for purposes of illustration and description. Further, the description is not intended to limit the invention to the form disclosed herein. Consequently, variations and modifications commensurate with the above teachings, within the skill or knowledge of the relevant art, are within the scope of the present invention. The embodiments described here and above are further intended to explain the best mode presently known of practicing the invention and to enable others skilled in the art to utilize the invention in such and/or other embodiments and with the various modifications required by their particular application or use of the invention. It is intended that the appended claims be construed to include alternative embodiments to the extent permitted by the prior art.

What is claimed is:

1. A method for reducing surface energy, comprising:
providing a substrate comprising at least a first surface;
establishing at least a partial vacuum in a volume in communication with said first surface;
introducing at least one fluorocarbon precursor gas to said volume;
maintaining said fluorocarbon precursor gas in said volume at a first minimum pressure or greater;
providing energy to said volume, wherein a fluorocarbon material is formed at said first surface.

2. The method of claim 1, wherein the energy provided to said volume is at least one energy selected from the group consisting of electromagnetic radiation and thermal energy.

3. The method of claim 1, further comprising:
electrically grounding said first surface prior to providing energy to said volume.

4. The method of claim 1, further comprising:
introducing an electrical bias to said first surface.

5. The method of claim 1, further comprising:
introducing a pulsed electrical bias to said first surface.

6. The method of claim 1, wherein said fluorocarbon precursor gas comprises at least one of C₃F₆ and C₃F₈.

7. The method of claim 1, further comprising:
introducing at least one inert gas with the fluorocarbon precursor gas to said volume.

8. The method of claim 1, wherein said substrate comprises an element of an optical system.

9. The method of claim 1, wherein a film having a thickness of less than about 100 nm is formed on said first surface.

10. The method of claim 1, wherein a film having a thickness of less than 50 Å is formed on said first surface.

11. The method of claim 1, wherein a thin film having a thickness of approximately 7 Å is formed on said first surface.

12. The method of claim 1, wherein a thickness of said substrate is reduced.

13. The method of claim 1, wherein a root mean-square roughness of said first surface is increased during modification.

14. The method of claim 1, wherein a surface energy of said first surface is less than 25 dyne/cm.

15. The method of claim 1, wherein a surface energy of said first surface is less than 20 dyne/cm.

16. The method of claim 1, wherein less than 15% of said surface energy is polar.

17. The method of claim 1, wherein less than 5% of said surface energy is polar.

18. The method of claim 1, wherein said fluorocarbon material is fluorinated diamond-like carbon.

19. The method of claim 1, wherein said first surface is nanotextured.

20. The method of claim 1, wherein said first surface is an active or passive, electrically or magnetically functioning surface.

21. The method of claim 1, wherein the energy provided to said volume is varied to produce a graded fluorocarbon material.

22. The method of claim 1, wherein the energy provided to said volume is reduced as the fluorocarbon material is formed, with more energy initially and less at the completion of the deposition.

23. A method for reducing surface energy, comprising:
providing a substrate comprising at least a first surface;
providing a solid precursor;
establishing at least a partial vacuum in a volume in communication with said first surface;
introducing at least one reactant gas;
maintaining said reactant gas in said volume at a first minimum pressure or greater;
providing energy to said solid precursor, wherein a fluorocarbon material is formed at said first surface.

24. A treated surface formed by a method comprising:
providing a substrate comprising at least a first surface;
establishing at least a partial vacuum in a volume in communication with said first surface;
introducing a fluorocarbon precursor gas to said volume;
maintaining said fluorocarbon precursor gas in said volume at a first minimum pressure or greater;
providing energy to said volume, to form a fluorinated coating having a thickness of less than about 100 Å on said first surface.

25. The treated surface of claim 24, wherein said fluorinated coating comprises a fluorinated Carbon lattice having a thickness between about 10 Å and about 90 Å.

26. The treated surface of claim 24, wherein said fluorinated diamond-like Carbon coating comprises a fluorinated diamond-like Carbon lattice having a thickness between about 20 Å and about 50 Å.

27. A treated surface formed by a method comprising:
providing a substrate comprising at least a first surface;
establishing at least a partial vacuum in a volume in communication with said first surface;
introducing a fluorocarbon precursor gas to said volume;
maintaining said fluorocarbon precursor gas in said volume at a first minimum pressure or greater;
providing energy to said volume, wherein said first surface is chemically modified to comprise a fluorinated carbon surface with low surface energy.
